(19) United States
(12) Patent Application Publication
(10) Pub. No.: US 2009/0315104 A1
(43) Pub. Date: Dec. 24, 2009

(54) Trench MOSFET with shallow trench structures

(75) Inventor: Fu-Yuan Hsieh, Kaohsiung (TW)

Correspondence Address: BACON & THOMAS, PLLC, 625 SLATERS LANE, FOURTH FLOOR, ALEXANDRIA, VA, 22314-1176, US

(73) Assignee: FORCE MOS TECHNOLOGY CO. LTD., Kaohsiung (TW)

(21) Appl. No.: 12/385,898

(22) Filed: Apr. 23, 2009

Related U.S. Application Data
(63) Continuation-in-part of application No. 12/143,714, filed on Jun. 20, 2008.

(51) Int. Cl. H01L 29/78; H01L 21/336

(52) U.S. Cl. 257/330; 438/270; 257/342; 257/E29.257; 257/E29.262; 257/E21.41

(57) ABSTRACT

A trench MOSFET with shallow trench structure is disclosed. The improved structure resolves the problem of degradation of BV caused by the As Ion Implantation in termination surface and no additional mask is needed which further enhance the avalanche capability and reduce the manufacture cost.

### CROSS REFERENCE TO RELATED APPLICATION

This application is a continuation in part of U.S. patent application Ser. No. 12/143,714 filed on Jun. 20, 2008.

### BACKGROUND OF THE INVENTION

1. Field of the Invention

This invention relates generally to the cell configuration and fabrication process of trench MOSFET devices. More particularly, this invention relates to a novel and improved cell and termination structure, and improved process of fabricating a trench MOSFET with shallow trench structures having reduced drain-source resistance (Rds), and reduced gate charge (Qg), while maintaining a high Breakdown Voltage (BV).

2. The Prior Arts

Please refer to FIG. 1 for a trench MOSFET of prior art. In order to resolve the problem of high gate charge introduced in trench MOSFET of conventional configuration, shallow trench structures is disclosed by decreasing trench depth. However, the decrease in trench depth will lead to increase of Rds as shown in FIG. 3 (No As I/I curve). On the other hand, if the trench depth is shallow, when etching the gate contact trench during fabricating process, it is possible to etch through doped polysilicon filled in gate trench and further penetrate through the gate oxide and result in a shortage of metal plug filled in trench gate contact to the epitaxial layer.

Accordingly, it would be desirable to provide a power MOSFET with shallow trench structure having lower gate charge, lower Rds and higher BV.

### SUMMARY OF THE INVENTION

It is therefore an object of the present invention to provide new and improved power MOSFET with shallow trench structure and manufacture process to resolve the problems mentioned above. An additional Ion Implantation region with the same doping type as epitaxial layer and higher concentration is formed below the trench gate bottoms, as marked by 111 in FIG. 2, to achieve lower Qg without significantly increasing Rds, where the trench MOSFET is represented by an N-channel device. FIG. 3 shows the two different simulated relationship of the difference between trench depth Td and P body depth Pd (both illustrated in FIG. 2) and Rds, indicating that Rds is significantly reduced with introduction of As I/I into trench bottom, and furthermore, in FIG. 4, the dashed line indicates the concentration of its epitaxial layer, from which can be seen that, the concentration of the n* area is heavier than that of epitaxial layer.

One aspect of the present invention is that, in some preferred embodiments, a metal field plate is employed overlying body region and top surface of epitaxial layer with trench bottom Ion Implantation, as indicated in FIG. 5. The breakdown voltage BV of the device is maintained same (breakdown still initially occurs at trench gate corner) although the BV in termination is slightly degraded as result of introduction of the trench bottom Ion Implantation.

Another aspect of the present invention is that, in some preferred embodiments, the BV degradation in termination can be totally prevented without introducing the trench bottom Ion Implantation dopant into top surface of epitaxial layer by blocking the Ion Implantation with mask oxide used as hard mask for trench etching for trench gates. Meanwhile, no additional mask is required to achieve this structure because during the trench bottom Ion Implantation, the Ion is blocked by thick oxide covering top surface of epitaxial layer.

Another aspect of the present invention is that, in some preferred embodiments, terrace gates for gate connection is employed to avert shortage issue may caused by trench gate contacts penetrating trench gate bottoms.

Briefly, in a preferred embodiment as shown in FIG. 5, the present invention disclosed a trench MOSFET with shallow trench structure formed on a heavily doped substrate of a first semiconductor doping type (e.g., N type) coated with back metal (not shown) on rear side as drain. Onto said substrate, a lightly doped epitaxial layer of a same first semiconductor doping type is grown, and a plurality of trenches is etched wherein, especially, the trench for gate connection is wider than others. Doped poly is filled into said trenches with a gate insulation layer formed over the inner surface of said trenches to form trenched gates. A body region that is doped with a dopant of second conductivity type (e.g., P type), extends between every two adjacent trench gates. The bottom of each said trench is designed to be rounded and wrapped with a doping area which has same doping type and heavier doping concentration comparing to epitaxial layer and is marked as n* in FIG. 5. Source regions heavily doped with a first doping type (e.g., N type) are formed on top surface of the P body regions. Through a thick oxide layer deposited over epitaxial layer, source-body contact trenches and gate contact trenches are etched into epitaxial layer and trench gates for source-body connection and gate connection, respectively. At the bottom of each source-body contact trench, a contact area heavily doped with the second doping type ion (e.g., P type) is carried out, which will help to form a low-resistance contact between contact metal plug and said body region. Tungsten plugs acting as the contact metal are filled into those contact trenches to connect the source regions, the body regions and the trench gates to source metal and gate metal, respectively. Said gate metal also serves as metal field plate overlying P body and top surface of epitaxial layer with Ion Implantation dopant in termination. The metal field plate is beyond P body and overlap the epitaxial layer surface ranging from 2 to 10 um, which can alleviate the BV degradation caused by n* area on top surface of epitaxial layer in termination.

In another preferred embodiment as shown in FIG. 6, wherein the trench MOSFET structure disclosed is similar to the structure mentioned in the first embodiment except that the connecting trench gate is designed to be terrace gate for prevention of W plug shortage to epitaxial layer through gate oxide, and the width of poly remained for gate metal contact is not greater than that of trench gate to further improve gate oxide integrity, because of no overlap between terrace gate and top trench corner due to thinner gate oxide around trench corner.

In another preferred embodiment as shown in FIG. 7, wherein the trench MOSFET structure disclosed is similar to the structure mentioned in the first embodiment except that there is no n* area on top surface of epitaxial layer in termination due to the thick oxide covering top surface of epitaxial layer functioning as hard mask for trench bottom Ion Implantation during fabricating process.

In another preferred embodiment as shown in FIG. 8, wherein the trench MOSFET structure disclosed is similar to the structure mentioned in the second embodiment except that there is no n* area on top surface of epitaxial layer in termination due to the thick oxide covering top surface of epitaxial layer functioning as hard mask for trench bottom Ion Implantation during fabricating process.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a side cross-sectional view of a trench MOSFET of prior art.

FIG. 2 is a side cross-sectional view of a cell portion of a trench MOSFET with shallow trench structure and trench bottom Ion Implantation.

FIG. 3 is a profile showing the dependence of Rds on difference between trench depth and P body depth in an N-channel MOSFET. The upper curve indicates the condition with no arsenic implantation at the bottom of the trench, while the lower one indicates the condition with an n* area at the bottom of the trench.

FIG. 4 is a profile illustrating the doping concentration distributed along channel region from silicon surface in an N-channel MOSFET.

FIG. 5 is a side cross-sectional view of a shallow trench MOSFET of an embodiment according to the present invention.

FIG. 6 is a side cross-sectional view of a shallow trench MOSFET of another embodiment according to the present invention.

FIG. 7 is a side cross-sectional view of a shallow trench MOSFET of another embodiment according to the present invention.

FIG. 8 is a side cross-sectional view of a shallow trench MOSFET of another embodiment according to the present invention.

FIGS. 9A to 9E are a serial of side cross sectional views for showing the processing steps for fabricating a shallow trench MOSFET as shown in FIG. 8.

FIGS. 10A to 10B are a serial of side cross sectional views for showing the processing steps for fabricating a shallow trench MOSFET as shown in FIG. 9.

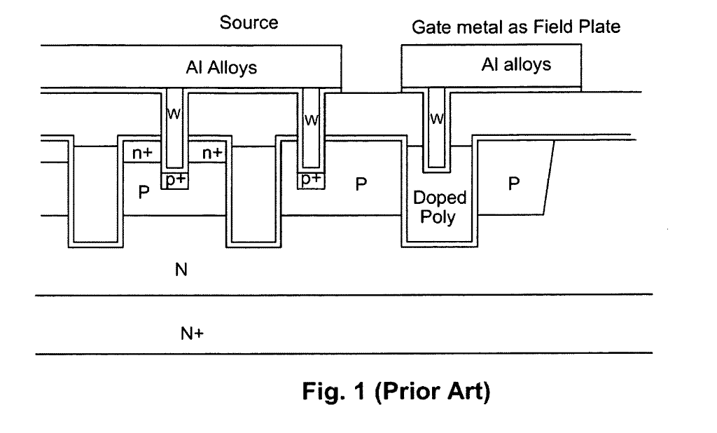

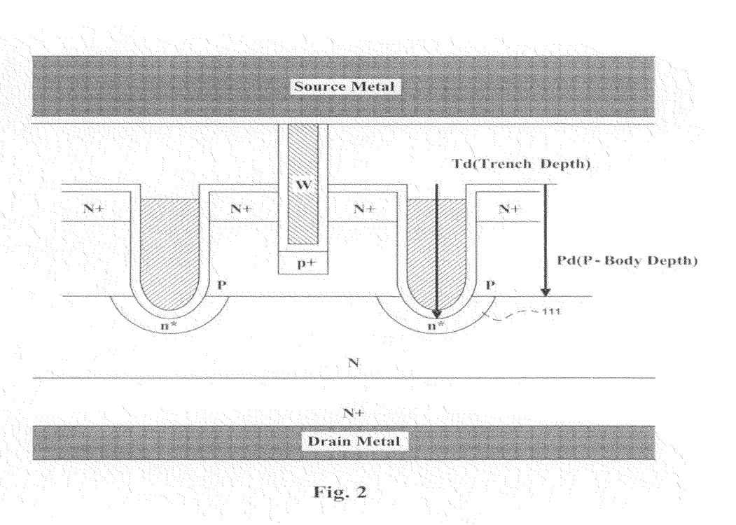

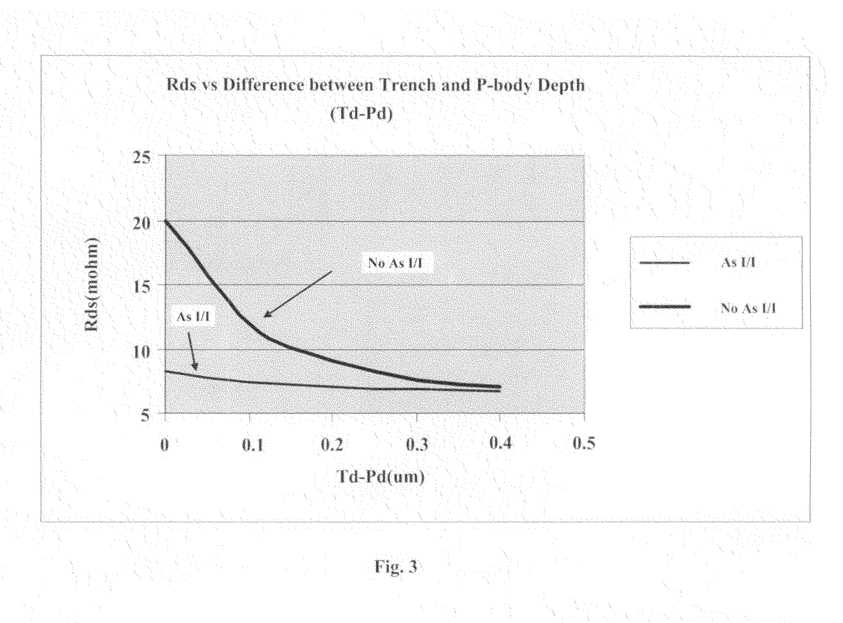

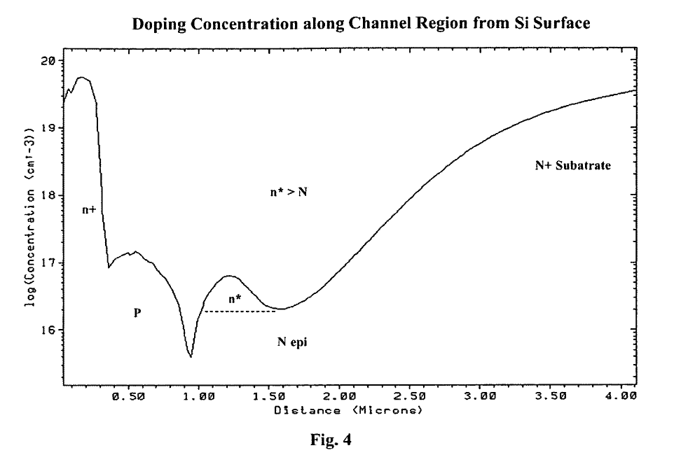

### DETAILED DESCRIPTION OF THE EMBODIMENTS

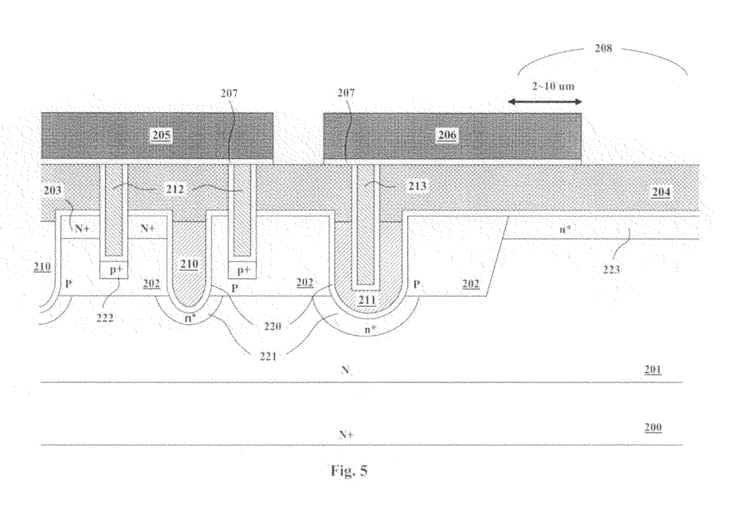

Please refer to FIG. 5 for a preferred embodiment of this invention where a trench MOSFET with shallow trench structure formed on a heavily N+ doped substrate 200 coated with back metal (not shown) on rear side as drain. Onto said substrate 200, a lightly N doped epitaxial layer 201 is grown, and a plurality of trenches is etched wherein. Doped poly is filled into said trenches with a gate insulation layer 220 formed over the inner surface of said trenches to form trenched gates 210 and at least a wider trench gate 211 for gate connection. A P body region 202 extends between said trench gates 210 and 211 with N+ source regions 203 near the top surface. The bottom of each trench is designed to be rounded and wrapped with an n* area 221 which has heavier doping concentration than the epitaxial layer 201. Trench source-body contacts filled with tungsten plug 212 is formed penetrating through a thick oxide layer 204 with contact p+implantation area 222 right below each source-body contact bottom. Meanwhile, at least a trench gate contact filled with tungsten plug 213 is formed also penetrating the thick oxide layer 204 and into wider trench gate 211. Above a resistance-reduction interlayer 207 of Ti or Ti/TiN, source metal 205 and gate metal 206 are deposited to connect with source and body region via trench source-body contact 212, and to connect with trench gate via trench gate contacts 213, respectively. Said gate metal 206 also serves as metal field plate overlying P body 202 and top surface of epitaxial layer 201 with ION IMPLANTATION dopant in termination 208. The metal field plate beyond P body 202 and overlap the epitaxial layer 201 surface ranging from 2 to 10 um, which can alleviate the BV degradation caused by n* area 223 on top surface of epitaxial layer 201 in termination 208.

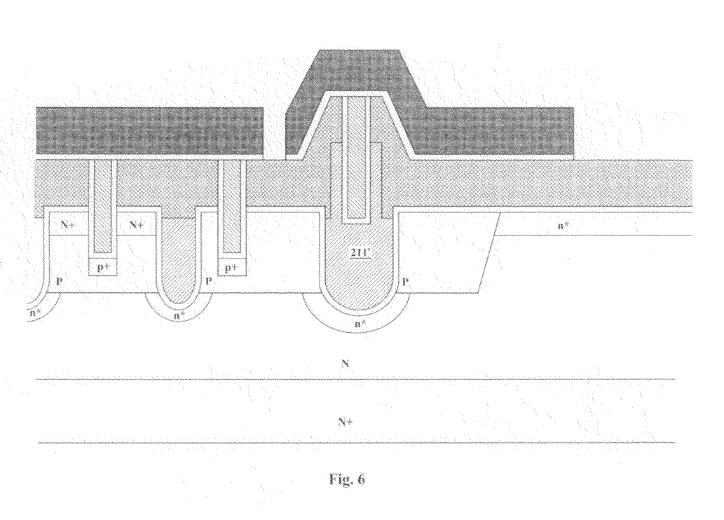

FIG. 6 shows another preferred embodiment of the present invention. Compared to FIG. 5, for the purpose of avoiding the connecting trench penetrating through oxide layer and resulting in shortage of tungsten plug to epitaxial layer, a terrace poly gate 211′ is designed. Therefore, an additional poly mask is needed here to form said terrace poly gate 211′ above wide trench, which can effectively lift the gate contact trench to a higher place to avoid the tungsten plug penetrating through oxide layer.

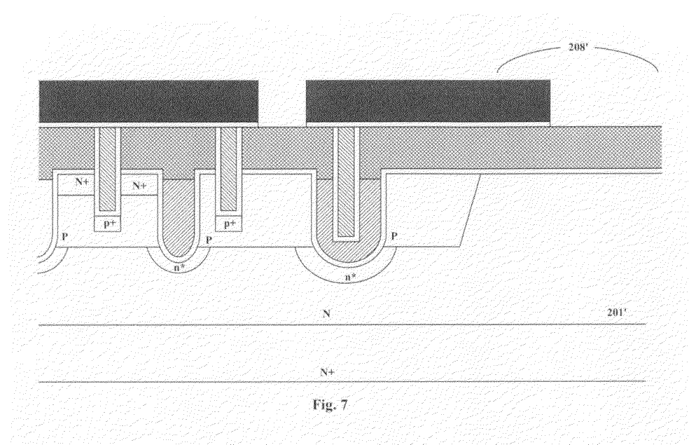

FIG. 7 shows another preferred embodiment of the present invention. The shown MOSFET has a similar structure to that in FIG. 5 except that there is no n* area on top surface of epitaxial layer 201′ in termination 208′ due to the employment of a thick oxide functioning as hard mask covering top surface of epitaxial layer during trench bottom Ion Implantation process.

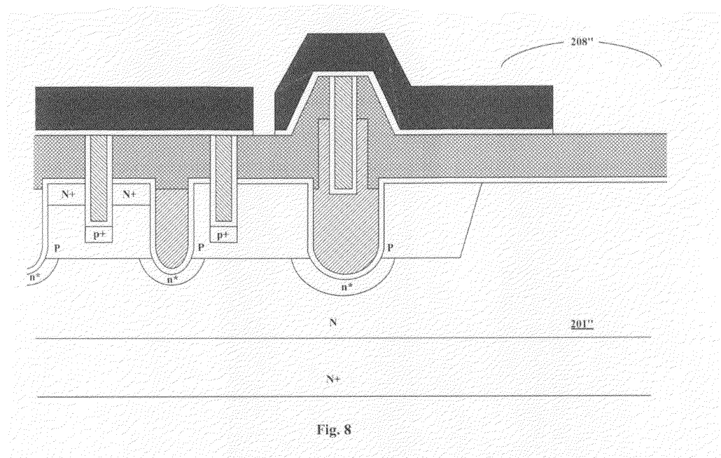

FIG. 8 shows another preferred embodiment of the present invention. The shown MOSFET has a similar structure to that in FIG. 5 except that there is no n* area on top surface of epitaxial layer 201″ in termination 208″ due to the employment of a thick oxide functioning as hard mask covering top surface of epitaxial layer during trench bottom Ion Implantation process.

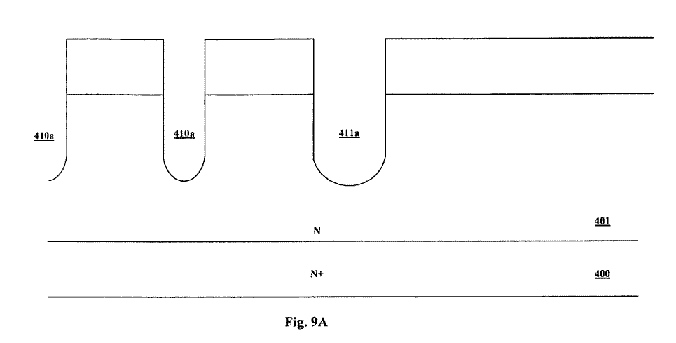

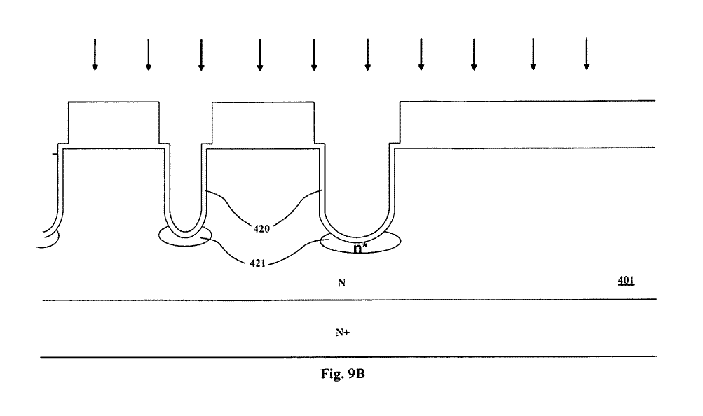

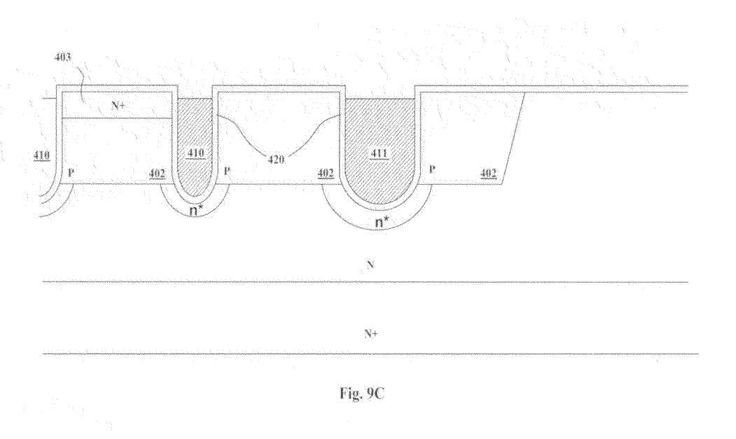

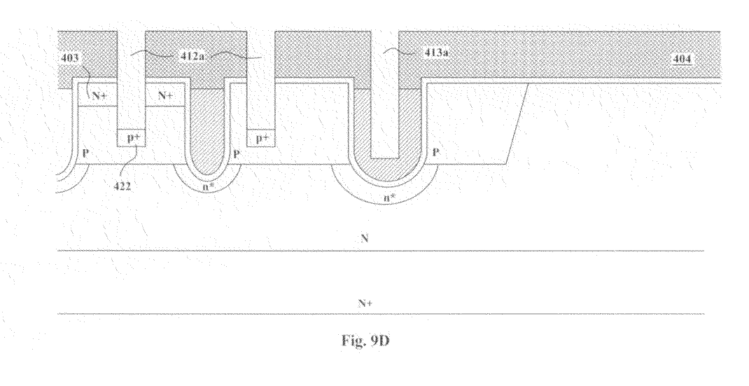

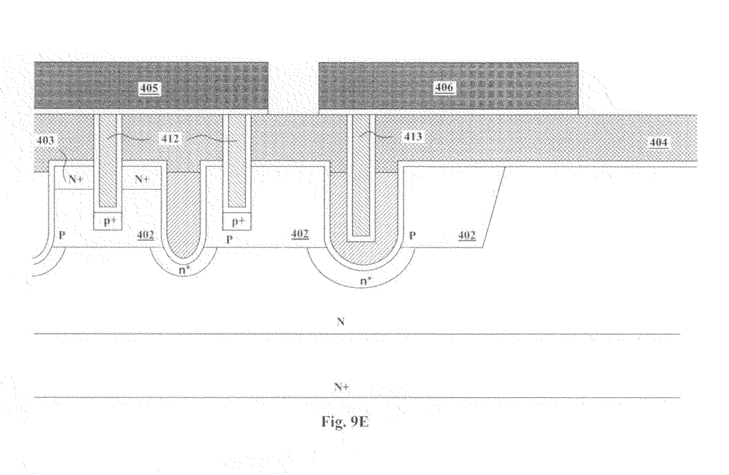

FIGS. 9A to 9E show a series of exemplary steps that are performed to form the inventive trench MOSFET with shallow trench structure of the third embodiment shown in FIG. 7. In FIG. 9A, an N doped epitaxial layer 401 is grown on an N+ doped substrate 400. A hard mask (oxide or oxide/nitride/oxide) is deposited onto epitaxial layer 401. Thereafter, a trench mask (not shown) is applied onto said hard mask for the formation of a plurality of gate trenches 410a and at least a wider gate trench 411a by a consequently hard mask etching, photo-resist removing and dry silicon trench etching. After all the trenches etched to a certain depth, in FIG. 9B, sacrificial oxide (not shown) is grown and then removed to eliminate the plasma damage introduced during opening those gate trenches. Then, a layer of oxide is grown as screen for the followed As Ion Implantation step to form n* area 421 underneath each trench with doping concentration heavier than that of said epitaxial layer 401 to further reduce Rds. Next, in FIG. 9C, after the screen oxide and the hard mask removal, gate oxide 420 is formed along the front surface of device and the inner surface of said trenches 410a and 411a. Then, all trenches are filled with doped poly or combination of doped poly and non-doped poly and followed by a step of poly CMP (Chemical Mechanical Polishing) or etching back to form trench gate 410 and at least a wider trench gate 411 for gate connection. For further reducing gate resistance, a layer of silicide (not shown) is formed on top of poly as alternative. After the P type dopant Ion Implantation for the formation of P body 402, a diffusion step for P body drive-in is carried out. Then, a second mask (not shown) is applied to form N+ source region 403, followed by an N dopant Ion Implantation and diffusion step for source region drive-in.

In FIG. 9D, the process continues with the deposition of thick oxide layer 404 over entire structure. A contact mask is applied to carry out a contact etch to open the contact opening 412a for source-body contact and 413a for gate contact by applying a dry oxide etch through the oxide layer 404 and followed by a dry silicon etch to open the contact openings 412a and 413a. A BF2 Ion Implantation process is followed for the formation of contact hole 422 for further reducing the resistance between contact metal plug and P body region 402.

In FIG. 9E, tungsten metal plugs are filled into the trenched contact openings padded by a barrier layer composed of Ti/TiN or Co/TiN to form trench source-body contact 412 and trench gate contact 413. Then, a tungsten etching back and Ti/TiN etching back is performed followed by metal layer formation of successive Ti or Ti/TiN and Al alloys. A metal mask is applied to pattern the metal layer into a source metal 405 and a gate metal layer 406. The source metal 405 is in electrical contact with source and body region via the trench source-body contact, while the gate metal 406 is in electrical contact with the trench gate via trench gate contact. Said gate metal is used to function as metal field plate as well.

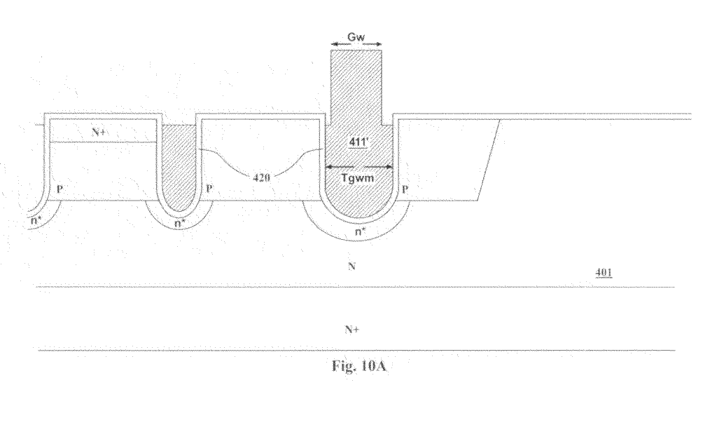

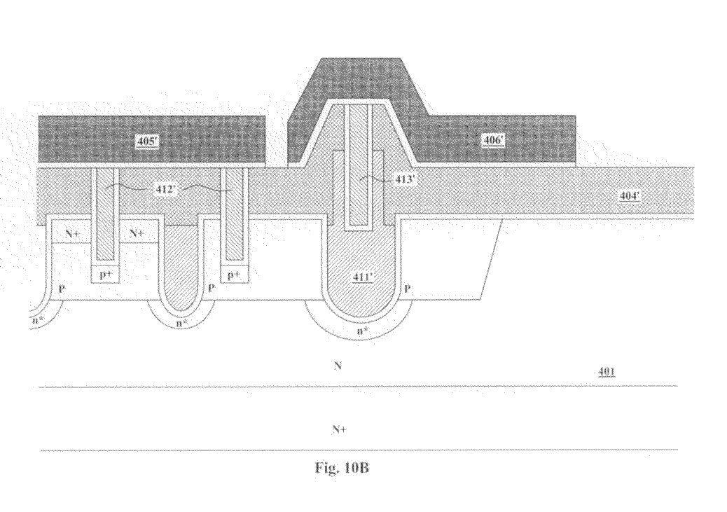

FIGS. 10A to 10B shows a series of exemplary steps that are performed to form the inventive trench MOSFET with shallow trench structure of another preferred embodiment shown in FIG. 8. In FIG. 10A, with former steps the same as steps fabricating structure in FIG. 7 until the deposition of doped poly or combination of doped poly and non-doped poly into gate trenches. The difference is that the connecting trench gate 411′ is designed to be terrace gate for prevention of W plug shortage to epitaxial layer 401 through gate oxide 420. As illustrated in FIG. 10A, Tgwm represents the width of at least one wider trench for gate connection while Gw indicates the gate width above the trench gate 411′, e.g., the portion of poly remained for gate metal contact. Gw is designed to be smaller than Tgwm to improve gate oxide integrity, as no overlap between terrace gate and top trench corner due to thinner gate oxide around trench corner. Therefore, an additional mask is needed to form the terrace poly gate. With this method, the contact trench for gate contact is lifted to prevent the shortage of tungsten plug to epitaxial layer. In FIG. 10B, after the thick oxide 404′deposition, a contact mask is applied to carry out a contact etch to for contact trench openings. Then, tungsten metal plugs are filled into the those contact trenches padded by a barrier layer composed of Ti/TiN or Co/TiN to form trench source-body contact 412′ and trench gate contact 413′. Next, successively deposition of Ti or Ti/TiN and Al alloys is carried out and then patterned by a deposited metal mask to form source metal 405′ and gate metal 406′ respectively. Said gate metal is used to function as metal field plate as well.

The number of masks used in the two preferred embodiment mentioned above is different. In the third preferred embodiment, five masks is needed during entire process, while in the 4th preferred embodiment, an additional terrace poly mask is applied to implement the function of avoiding shortage problem, that is to say, six masks is needed.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A vertical semiconductor power MOS device comprising a plurality of semiconductor power cells with each cell comprising a trenched gate surrounded by a source region with first type conductivity encompassed in a body region with second type conductivity above a drain region disposed on a bottom surface of a low-resistivity substrate with first type conductivity, wherein said MOS cell further comprising:
an epitaxial layer with the first type conductivity is grown on the substrate;
an on-resistance reduction doped region underneath said trenched gate bottom with the first type conductivity having doping concentration higher than said epitaxial layer;
a first insulating layer serving as gate oxide lining the inner surface of openings for trench gates;
a second insulating layer functioning as thick oxide interlayer covering top surface of the epitaxial layer;
a source-body contact trench opened through said thick oxide interlayer and said source region, and extending into said body region;
a gate contact trench opened through said thick oxide interlayer and extending into trench-filling material in said trenched gate underneath metal gate runner, which is near termination served as metal field plate over said body region and said epitaxial region;
a tungsten plug filled into said source-body contact trench and said gate contact trench, and padded with a barrier layer.
a source metal layer and a gate metal layer formed over a resistance-reduction layer connected to said tungsten plug in said source-body contact trench and said gate contact trench, respectively;
a drain metal layer formed on a bottom surface of the MOSFET.

2. The MOSFET of claim 1, wherein said metal field plate overlying said body region and said on-resistance reduction region on top of said epitaxial layer.

3. The MOSFET of claim 1, wherein said metal field plate overlying said body region and said epitaxial layer without having said on-resistance reduction region.

4. The MOSFET of claim 1, wherein said trench gate for gate metal contact is wider than those in active area.

5. The MOSFET of claim 1, wherein said trench-filling material is doped poly.

6. The MOSFET of claim 1, wherein said trench-filling material is combination of doped poly and non-doped poly.

7. The MOSFET of claim 1, wherein said trench-filling material is doped poly with silicide on the poly top.

8. The MOSFET of claim 1, wherein the top level of said doped poly in said gate contact trench is same as that in said trench gates in active area.

9. The MOSFET of claim 1, wherein the top level of said doped poly in said gate contact trench is higher than that in said trench gates in active area.

10. The MOSFET of claim 1, wherein said barrier layer in source-body contact trench and gate contact trench is Ti/TiN or Co/TiN.

11. The MOSFET of claim 1, wherein said resistance-reduction layer is Ti or Ti/TiN.

12. A method for manufacturing a vertical semiconductor power device with shallow trench structures comprising the steps of:
growing an epitaxial layer upon a heavily doped substrate, wherein said epitaxial layer and said substrate are doped with a first type dopant, e.g., N dopant;
forming a thick oxide covering front surface of said epitaxial layer as hard mask for later trench bottom Ion Implantation;
forming a trench mask with open and closed areas on the surface of said hard mask;
removing semiconductor material from exposed areas of said trench mask to form a plurality of gate trenches;
growing a sacrificial oxide layer onto the surface of said trenches to remove the plasma damage introduced during opening said trenches;
removing said sacrificial oxide and growing a layer of screen oxide
implanting with As ion to form on-resistance reduction region with a net doping concentration higher than said epitaxial layer;
removing screen oxide layer and said hard mask;
growing a first insulating layer along the front surface of device and the inner surface of said trenches as gate oxide;
depositing doped poly or combination of doped poly and non-doped poly into all trenches onto said gate oxide;
etching back or CMP said gate oxide and said doped poly or combination of doped poly and non-doped poly;
forming body regions by P type ion implantation into the epitaxial layer followed by diffusion to drive in;
forming source regions by N type ion implantation near the top surface of body regions followed by diffusion;
depositing a second insulating layer onto whole surface as thick oxide interlayer;
forming a contact mask on the surface of said second insulating layer and removing the insulating material and semiconductor material;
implanting BF2 ion to form p+ area at the bottom of source-body contact trench within P body region;
depositing Ti/TiN/W or Co/TiN/W consequently into source-body contact trenches and gat contact trench to form source-body contact and trench gate contact;
etching back tungsten and Ti/TiN or Co/TiN;
depositing Al Alloys on front and rear surface of device, respectively, and forming source-metal and gate metal by pattering front metal with a metal mask.

13. The method of claim 12, wherein forming said gate trenches comprises etching said epitaxial layer according to the open areas of said trench mask by dry silicon etching.

14. The method of claim 12, wherein forming said trench gates comprises forming a trench gate with top surface of filling-in material higher than epitaxial layer by offering another gate mask.

15. The method of claim 12, wherein forming a layer of silicide on top of poly as alternative for further reducing gate resistance.

16. A method for manufacturing a vertical semiconductor power device with shallow trench structures comprising the steps of:
growing an epitaxial layer upon a heavily doped substrate, wherein said epitaxial layer and said substrate are doped with a first type dopant, e.g., N dopant;
forming a thick oxide covering front surface of said epitaxial layer as hard mask;
forming a trench mask with open and closed areas on the surface of said hard mask;
removing semiconductor material from exposed areas of said trench mask to form a plurality of gate trenches;
removing said hard mask by wet etch;
growing a sacrificial oxide layer onto the surface of said trenches to remove the plasma damage introduced during opening said trenches;
removing said sacrificial oxide and growing a layer of screen oxide
implanting with As ion to form on-resistance reduction region with a net doping concentration higher than said epitaxial layer;
removing screen oxide layer;
growing a first insulating layer along the front surface of device and the inner surface of said trenches as gate oxide;
depositing doped poly or combination of doped poly and non-doped poly into all trenches onto said gate oxide;
etching back or CMP said gate oxide and said doped poly or combination of doped poly and non-doped poly;
forming body regions by P type ion implantation into the epitaxial layer followed by diffusion to drive in;
forming source regions by N type ion implantation near the top surface of body regions followed by diffusion;
depositing a second insulating layer onto whole surface as thick oxide interlayer;
forming a contact mask on the surface of said second insulating layer and removing the insulating material and semiconductor material;
implanting BF2 ion to form p+ area at the bottom of source-body contact trench within P body region;
depositing Ti/TiN/W or Co/TiN/W consequently into source-body contact trenches and gat contact trench to form source-body contact and trench gate contact;
etching back tungsten and Ti/TiN or Co/TiN;
depositing Al Alloys on front and rear surface of device, respectively, and forming source-metal and gate metal by pattering front metal with a metal mask.

17. The method of claim 16, wherein forming said gate trenches comprises etching said epitaxial layer according to the open areas of said trench mask by dry silicon etching.

18. The method of claim 16, wherein forming said trench gates comprises forming a trench gate with top surface of filling-in material higher than epitaxial layer by offering another gate mask.

19. The method of claim 16, wherein forming a layer of silicide on top of poly as alternative for further reducing gate resistance.
